(19) United States
(12) Patent Application Publication
(10) Pub. No.: US 2014/0367659 A1
(43) Pub. Date: Dec. 18, 2014

(54) DISPLAY DEVICES

(71) Applicant: SAMSUNG ELECTRONICS CO., LTD., Suwon-Si (KR)

(72) Inventors: KyongSoon CHO, Incheon (KR); Jae-Min JUNG, Seoul (KR); Jeong-Kyu HA, Hwaseong-si (KR)

(73) Assignee: SAMSUNG ELECTRONICS CO., LTD., Suwon-Si (KR)

(21) Appl. No.: 14/279,170

(22) Filed: May 15, 2014

(30) Foreign Application Priority Data
Jun. 12, 2013 (KR) 10-2013-0067235

(51) Int. Cl. H01L 27/32

(52) U.S. Cl. CPC H01L 27/3251
USPC 257/40

(57) ABSTRACT

A display device includes a substantially planar semiconductor package. The semiconductor package drives unit display elements of the display device. The semiconductor package is not folded and has a flat structure. Thus, the occurrence of defects and/or errors in the display device may be reduced as compared to display devices including folded non-planar semiconductor packages. As a result, reliability of the display device may be improved.

### CROSS-REFERENCE TO RELATED APPLICATION

This U.S. non-provisional patent application claims priority under 35 U.S.C. §119 to Korean Patent Application No. 10-2013-0067235, filed on Jun. 12, 2013, in the Korean Intellectual Property Office, the disclosure of which is hereby incorporated by reference in its entirety.

### TECHNICAL FIELD

The inventive concepts relate to display devices.

### BACKGROUND

Cathode ray tube (CRT) display devices are being replaced with liquid crystal display (LCD) devices that are in high demand because they provide light and thin monitors and/or televisions. However, since LCD devices are passive light emitting devices, they need additional backlight units. Additionally, LCD devices have slow response speeds and narrow viewing angles. Recently, organic light emitting diode (OLED) display devices have been proposed in order to overcome the above limitations of LCD devices. Unit display elements of OLED display devices are controlled by a driving circuit. The driving circuit may be installed by a tape carrier package method. However, the driving circuit is commonly installed such that a tape carrier package is folded, resulting in defects and/or errors in OLED display devices.

### SUMMARY

Embodiments of the inventive concepts may provide display devices with improved reliability.

According to an aspect of the inventive concepts, a display device may include a display substrate, a plurality of unit display elements, a first connection terminal, a circuit substrate, and a semiconductor package. The display substrate includes a display region and a non-display region. The plurality of unit display elements are disposed on the display substrate in the display region. The first connection terminal is disposed on the display substrate in the non-display region, and is electrically connected to at least one of the unit display elements. The circuit substrate is disposed on the display substrate in the non-display region, and the semiconductor package is disposed on the display substrate in the non-display region. The semiconductor package electrically connects the circuit substrate to the first connection terminal. The semiconductor package may be flat.

In some embodiments, the semiconductor package may include a package substrate, a second connection terminal disposed on a bottom surface of the package substrate, third and fourth connection terminals spaced apart from each other on a top surface of the package substrate, and a through-via penetrating the package substrate to electrically connect the second connection terminal to the third connection terminal. The first connection terminal may be electrically connected to the second connection terminal, and the circuit substrate may be electrically connected to the fourth connection terminal.

In some embodiments, the display device may further include a first interconnecting member disposed between the first and second connection terminals to electrically connect the first connection terminal to the second connection terminal. The first interconnecting member may be an anisotropic conductive film or a solder ball.

In some embodiments, the package substrate may be flexible or hard.

In some embodiments, the semiconductor package may further include a semiconductor chip mounted on the package substrate and contacting the third and fourth connection terminals. A bottom surface of the semiconductor chip may be parallel to a top surface of the display substrate.

In some embodiments, the package substrate may be disposed under a portion of the circuit substrate. In such embodiments, the display device may further include a bracket disposed between the circuit substrate and the display substrate to support the circuit substrate. In some examples, the circuit substrate may further include a fifth connection terminal disposed on a bottom surface of the circuit substrate, and the display device may further include a second interconnecting member disposed between the fifth and fourth connection terminals to electrically connect the fifth connection terminal to the fourth connection terminal. The second interconnecting member may be an anisotropic conductive film or a solder ball.

In some embodiments, the circuit substrate may be bonded to the display substrate. In such embodiments, the circuit substrate may further include a fifth connection terminal disposed on a top surface of the circuit substrate, and the display device may further include a third interconnecting member electrically connecting the fifth connection terminal to the fourth connection terminal. The third interconnecting member may be a wire.

In some embodiments, the display device may further include a frame surrounding the display substrate, the circuit substrate, and the semiconductor package. The frame may include an opening disposed so as to be aligned with the display region in a direction of light emission from the unit display elements. In such embodiments, each of the plurality of unit display elements may include at least one driving transistor TR and at least one organic light emitting diode disposed on one surface of the display substrate. In some such embodiments, the opening may be disposed adjacent to the one surface of the display substrate. Alternatively, the opening may be disposed adjacent to a surface of the display substrate opposite to the one surface.

In some embodiments, each of the unit display elements may include a unit switching element and a unit light emitting element.

In some embodiments, the display device may be an organic light emitting diode display device.

In some embodiments, all edges of the package substrate may be disposed at the same height.

According to another aspect of the inventive concepts, a display device may include a display substrate, a plurality of unit display elements, a circuit substrate, and a package substrate. The plurality of unit display elements are disposed in a display region of the display substrate, and each of the plurality of unit display elements includes at least one driving transistor and at least one organic light emitting diode. The circuit substrate is disposed on the display substrate and includes circuitry for driving organic light emitting diodes (OLEDs) of the plurality of unit display elements. The package substrate is disposed on the display substrate, is planar, and is configured to electrically connect the circuitry of the circuit substrate to the OLEDs of the plurality of unit display elements via driving transistors of the plurality of the plurality of unit display elements.

In some embodiments, the package substrate has a rectangular cuboid structure.

In some embodiments, the display device further includes a semiconductor chip disposed on the package substrate, wherein the circuitry of the circuit substrate is electrically connected to the OLEDs of the plurality of unit display elements via the semiconductor chip.

### BRIEF DESCRIPTION OF THE DRAWINGS

The inventive concepts will become more apparent in view of the attached drawings and accompanying detailed description.

FIG. 1 is a cross-sectional view illustrating a display device according to some embodiments of the inventive concepts;

FIGS. 2 to 5 are cross-sectional views illustrating a method of manufacturing the display device of FIG. 1;

FIGS. 6 and 7 are layouts illustrating display devices according to other embodiments of the inventive concepts;

FIGS. 8 to 11 illustrate examples of a multimedia device applied with a display device according to embodiments of the inventive concepts.

### DETAILED DESCRIPTION

The inventive concepts will now be described more fully hereinafter with reference to the accompanying drawings, in which exemplary embodiments of the inventive concepts are shown. The advantages and features of the inventive concepts and methods of achieving them will be apparent from the following exemplary embodiments. It should be noted, however, that the inventive concepts are not limited to the following exemplary embodiments, and may be implemented in various forms. Accordingly, the exemplary embodiments are provided only to disclose the inventive concepts and let those skilled in the art know the category of the inventive concepts. In the drawings, embodiments of the inventive concepts are not limited to the specific examples provided herein, and features shown in the drawings may be exaggerated for clarity.

The terminology used herein is for the purpose of describing particular embodiments only and is not intended to limit the invention. As used herein, the singular terms “a,” “an,” and “the” are intended to include the plural forms as well, unless the context clearly indicates otherwise. As used herein, the term “and/or” includes any and all combinations of one or more of the associated listed items. It will be understood that when an element is referred to as being “connected” or “coupled” to another element, it may be directly connected or coupled to the other element or intervening elements may be present.

Similarly, it will be understood that when an element such as a layer, region or substrate is referred to as being “on” another element, it can be directly on the other element or intervening elements may be present. In contrast, the term “directly” means that there are no intervening elements. It will be further understood that the terms “comprises”, “comprising,”, “includes,” and/or “including”, when used herein, specify the presence of stated features, integers, steps, operations, elements, and/or components, but do not preclude the presence or addition of one or more other features, integers, steps, operations, elements, components, and/or groups thereof.

Additionally, while certain embodiments in the detailed description will be shown and described using cross-sectional views, the embodiments are three dimensional structures having cross-sections corresponding to the drawings. Furthermore, shapes of the exemplary views may be modified according to manufacturing techniques and/or allowable errors. Therefore, the embodiments of the inventive concepts are not limited to the specific shapes illustrated in the exemplary views, but may include other shapes that may be created according to various manufacturing processes. Structures, elements, and cross-sectional areas are shown in the drawings as having specific shapes, although the structures, elements, and areas may have shapes different from those shown although they generally have similar properties as those shown in the drawings. Thus, the embodiments illustrated in the drawings should not be construed as limiting the scope of the inventive concepts.

It will be also understood that although the terms first, second, third, etc. may be used herein to describe various elements, these elements should not be limited by these terms. These terms are only used to distinguish one element from another element. Thus, a first element in some embodiments could be termed a second element in other embodiments without departing from the teachings of the present invention. Exemplary embodiments of aspects of the present inventive concepts explained and illustrated herein include their complementary counterparts. The same reference numerals or the same reference designators denote the same or similar elements throughout the specification.

Moreover, exemplary embodiments are described herein with reference to cross-sectional illustrations and/or plane illustrations that are idealized exemplary illustrations. Accordingly, variations from the shapes of the illustrations as a result, for example, of manufacturing techniques and/or tolerances, are to be expected. Thus, exemplary embodiments should not be construed as limited to the shapes of regions illustrated herein but are to include deviations in shapes that result, for example, from manufacturing. For example, an etching region illustrated as a rectangle will, typically, have rounded or curved features. Thus, the regions illustrated in the figures are schematic in nature and their shapes are not intended to illustrate the actual shape of a region of a device and are not intended to limit the scope of illustrative embodiments.

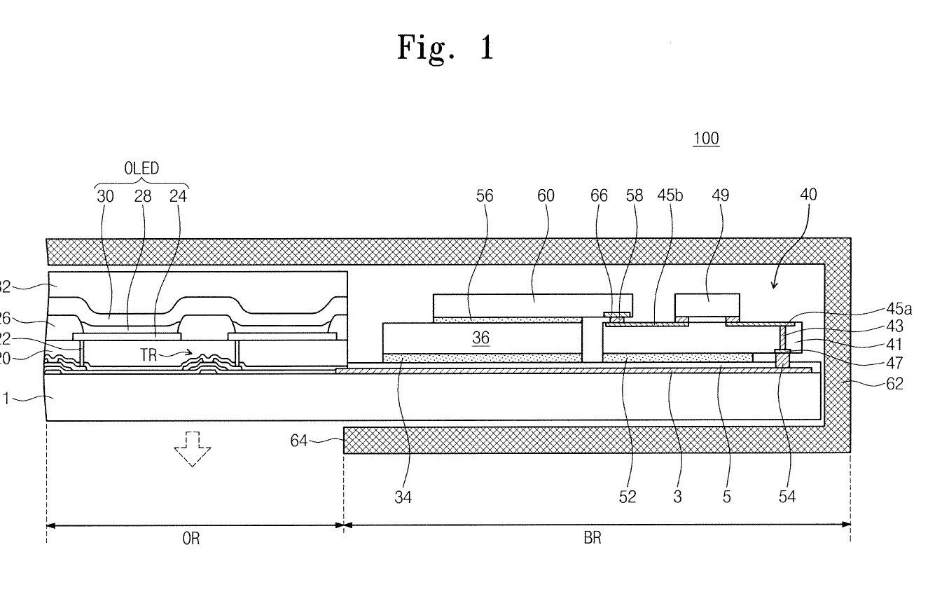

FIG. 1 is a cross-sectional view illustrating a display device according to some embodiments of the inventive concepts.

Referring to FIG. 1, a display device 100 according to the present embodiment may be an organic light emitting diode (OLED) display device. The display device 100 includes a display substrate 1. The display substrate 1 may be formed of a transparent material (e.g., glass). The display device 1 includes a display region OR and a non-display region BR. An image corresponding to inputted electrical signals is displayed in the display region OR. The image is not displayed in the non-display region BR. Driving circuits, used for driving unit display elements (e.g., each including at least one driving transistor TR and OLED) disposed in the display region OR, may be disposed in the non-display region BR. A plurality of the unit display elements are disposed on the display substrate 1 in the display region OR. Each of the unit display elements may include a unit switching element and a unit light emitting element. For example, each of the unit display elements may include a driving transistor TR and an organic light emitting diode OLED connected to the driving transistor TR. Even though not shown in the drawings, each of the unit display elements may further include a selection transistor and a storage capacitor.

The driving transistor TR is covered by an interlayer insulating layer 20. A contact plug 22 penetrating the interlayer insulating layer 20 electrically connects the driving transistor TR to the corresponding organic light emitting diode OLED. The organic light emitting diode OLED includes a pixel electrode 24, an organic light emitting member 28, and a common electrode 30. The pixel electrode 24 is disposed to correspond to each unit pixel region. The pixel electrode 24 may be formed of a transparent conductive material such as indium-tin oxide (ITO) or indium-zinc oxide (IZO). The organic light emitting member 28 may be formed of an organic material properly emitting light having any one base color, for example, any of the three primary colors including a red color, a green color, and a blue color. The display device 100 may display a desired image by spatial mixing of the base color light emitted from the organic light emitting members 28 of one or more OLEDs.

The organic light emitting member 28 may have a multi-layered structure including an emitting layer emitting light and an assistant layer for improving a light emitting efficiency of the emitting layer. The assistant layer may include an electron transport layer and a hole transport layer for balancing electrons and holes, and an electron injecting layer and a hole injecting layer for enhancing injection of electrons and holes.

The common electrode 30 may be continuously disposed throughout an entire surface of the display region OR. The common electrode 30 may be applied with a common voltage and may be formed of a transparent conductive material (e.g., ITO or IZO).

A partition 26 may be formed between the pixel electrodes 24 and between the organic light emitting members 28 of adjacent OLED pixels. The partition 26 may surround edges of the pixel electrodes 24 and the organic light emitting members 28 and form an embankment around the pixel electrodes 24 and organic light emitting members 28, thereby defining openings. The partition 26 may be formed of an organic insulating material or an inorganic insulating material. The partition 26 may be formed of a light sensitive material including a black pigment. In some examples, the partition 26 may act as a light shielding member.

An entire front surface of the common electrode 30 is covered by a sealing layer 32. The sealing layer 32 may protect the common electrode 30.

In the non-display region BR, a first connection terminal 3 is disposed on the display substrate 1. The first connection terminals 3 is electrically connected to at least one of the unit display elements (e.g., including an interconnected TR and OLED). A portion of the first connection terminal 3 may extend to have a line-shape. The extended portion of the first connection terminal 3 may be covered by a protection layer 5. One end portion of the first connection terminal 3 is electrically connected to a semiconductor package 40. The semiconductor package 40 may provide various electrical signals (e.g., driving signals) to the unit display elements of the display region OR. For example, the semiconductor package 40 may provide electrical signals to gate lines and data lines connected to the unit display elements.

The semiconductor package 40 includes a package substrate 41 and a semiconductor chip 49 mounted on the package substrate 41. The package substrate 41 is not folded but is flat and planar. Edges of the package substrate 41 may be disposed at the same height, and the package substrate may have a substantially parallelepiped rectangular cuboid structure. The package substrate 41 may be flexible or hard. A second connection terminal 47 is disposed on a bottom surface of the package substrate 41. The second connection terminal 47 is electrically connected to the first connection terminal 3 through a first interconnecting member 54. The first interconnecting member 54 may be an anisotropic conductive film, a solder ball, or a solder paste. Third and fourth connection terminals 45a and 45b spaced apart from each other are disposed on a top surface of the package substrate 41. The third and fourth connection terminals 45a and 45b may have a line-shape. The package substrate 41 may include a through-via 43 penetrating through the package substrate 41 from a top surface of the package substrate 41 to a bottom surface of the package substrate 41. The through-via 43 may electrically connect the third connection terminal 45a to the second connection terminal 47. The semiconductor chip 49 is in contact with the third and fourth connection terminals 45a and 45b, and circuitry of the semiconductor chip 49 may be electrically connected to the third and fourth connection terminals 45a and 45b. A bottom surface of the semiconductor chip 49 may be parallel to the top surface of the display substrate 1. The semiconductor package 40 may be bonded onto the display substrate 1 by using a first adhesive member 52.

The fourth connection terminal 45b is electrically connected to a circuit substrate 60. The circuit substrate 60 may be, for example, a printed circuit board (PCB). A fifth connection terminal 66 may be disposed on a bottom surface of the circuit substrate 60. The fifth connection terminal 66 may overlap with the fourth connection terminal 45b. A second interconnecting member 58 may be disposed between the fifth connection terminal 66 and the fourth connection terminal 45b to electrically connect the fifth and fourth connection terminals 66 and 56b to each other. The second interconnecting member 58 may be an anisotropic conductive film, a solder ball, or a solder paste. In the present embodiment, the bottom surface of the circuit substrate 60 may be higher than the top surface of the package substrate 41.

A bracket 36 may be disposed between the circuit substrate 60 and the display substrate 1 to fix and support the circuit substrate 60 on the display substrate 1. The bracket 36 may be bonded onto the display substrate 1 by a second adhesive member 34. The circuit substrate 60 may be bonded onto the bracket 36 by a third adhesive member 56.

The display device 100 further includes a frame 62 surrounding the display substrate 1, the circuit substrate 60, and the semiconductor package 40. The frame 62 may include an opening 64 overlapping with the display region OR. The opening 64 may be disposed to be adjacent to the bottom surface of the display substrate 1, and the display device 100 may transmit light toward the bottom surface of the display substrate 1 (e.g., in a direction of the dotted line arrow of FIG. 1), thereby displaying the image. In other words, the display device 100 may display the image in a bottom emission manner. The opening 64 may be disposed so as to be aligned with the display region OR in the direction of light transmission from the display device 100.

According to embodiments of the inventive concepts, since the package substrate 41 is flat and is not folded, cracks of the interconnecting members may be remarkably reduced. Thus, defects and/or errors of the display device 100 may be remarkably reduced to improve reliability of the display device 100. Additionally, since the semiconductor package 40 is not folded to a sidewall of the display substrate 1, an area of the non-display region BR may be reduced.

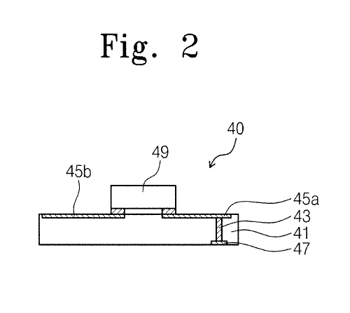

FIGS. 2 to 5 are cross-sectional views illustrating a method of manufacturing the display device of FIG. 1.

Referring to FIG. 2, a semiconductor package 40 is prepared. The semiconductor package 40 may be formed by mounting a semiconductor chip 49 on a package substrate 41. For example, the semiconductor chip 49 may be mounted using a flip chip bonding technique. The package substrate 41 may include a second connection terminal 47 on a bottom surface of the package substrate 41, third and fourth connection terminals 45a and 45b spaced apart from each other on a top surface of the package substrate 41, and a through-via 43 penetrating the package substrate 41 and electrically connecting the second connection terminal 47 and the third connection terminal 45a.

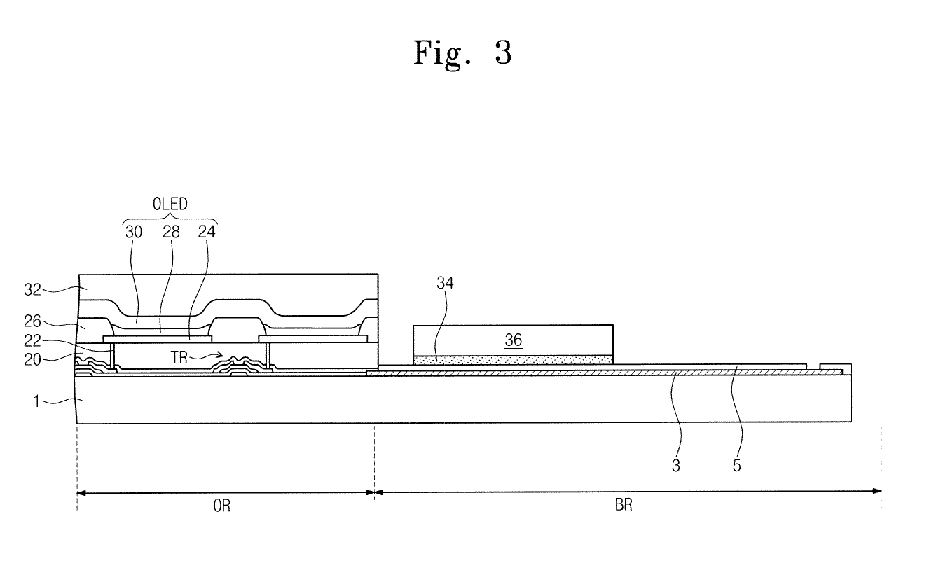

Referring to FIG. 3, a plurality of driving transistors TR, an interlayer insulating layer 20, contact plugs 26, organic light emitting diodes OLED, and a sealing layer 32 are formed in a display region OR of a display substrate 1. Additionally, a first connection terminal 3 electrically connected to unit display elements (e.g., each including at least one TR and one OLED) and a protection layer 5 covering a portion of the first connection terminal 3 are formed in a non-display region BR of the display substrate 1. In the non-display region BR, a bracket 36 may bonded to the substrate 1 (and/or to the protection layer 5) to be adjacent to the display region OR by a second adhesive member 34. At this time, the bracket 36 does not overlap with an end portion of the first connection terminal 3 that is not covered by the protection layer 5 and is exposed.

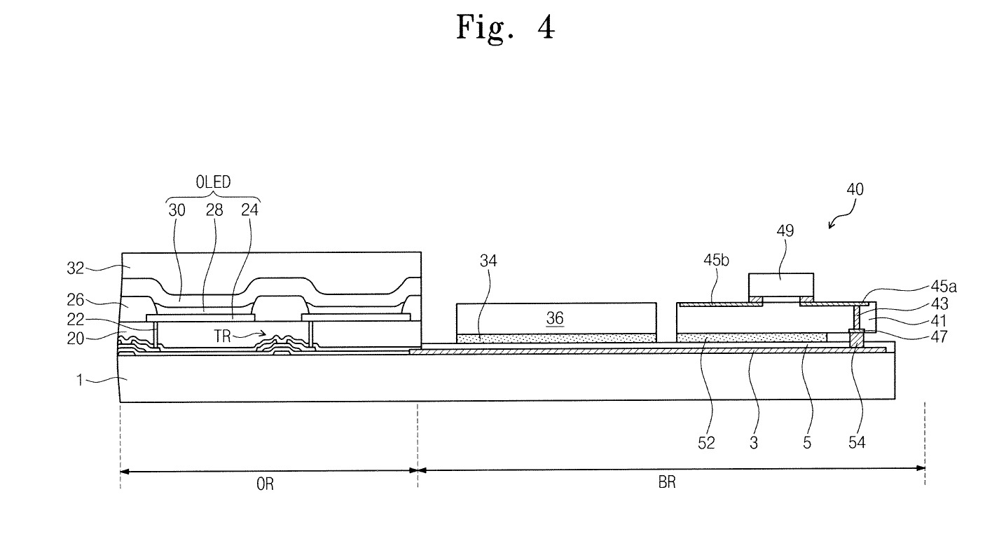

Referring to FIG. 4, the package substrate 41 is bonded onto the display substrate 1 using a first adhesive member 52 disposed therebetween in the non-display region BR so that the end portion of the first connection terminal 3 overlaps with the second connection terminal 47, and at the same time, a first interconnecting member 54 is inserted between the end portion of the first connection terminal 3 (including an exposed portion of the first connection terminal 3 that is not covered by the protection layer 5) and the second connection terminal 47. Thereafter, the first interconnecting member 54, the end portion of the first connection terminal 3, and the second connection terminal 47 are heated to melt and bond the first interconnecting member 54 to surfaces of the first connection terminal 3 and the second connection terminal 47.

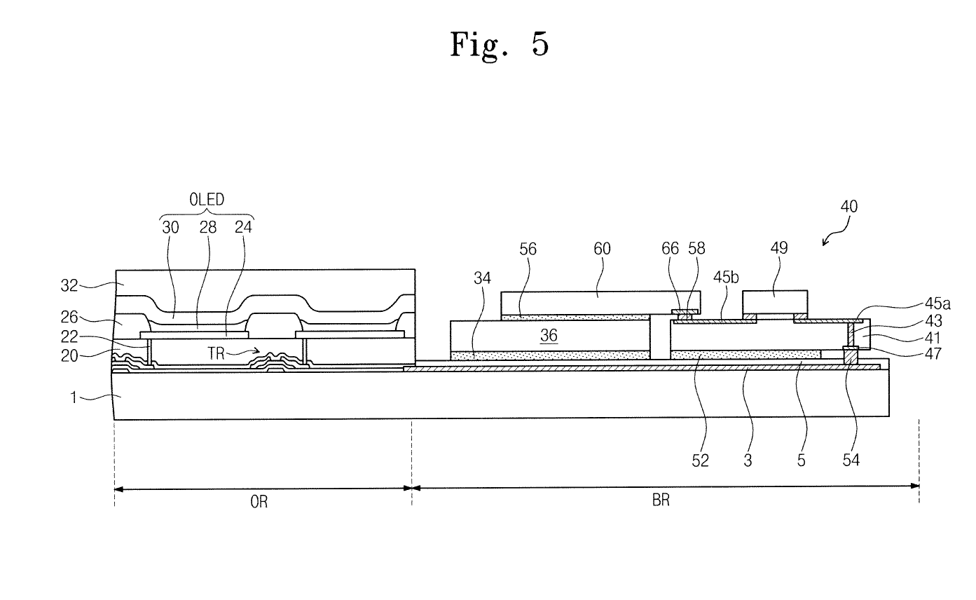

Referring to FIG. 5, the circuit board 60 is bonded onto the bracket 36 by a third adhesive member 56 so that a fifth connection terminal 66 overlaps with the fourth connection terminal 45b of the package substrate 41, and at the same time, a second interconnecting member 58 is inserted between the fifth connection terminal 66 and the fourth connection terminal 45b. Thereafter, the second interconnecting member 58 and the fourth and fifth connection terminals 45b and 66 are heated to melt and bond the second interconnecting member 58 to surfaces of the fourth and fifth connection terminals 45b and 66.

Subsequently, the display substrate 1 may be inserted in the frame 62 described with reference to FIG. 1.

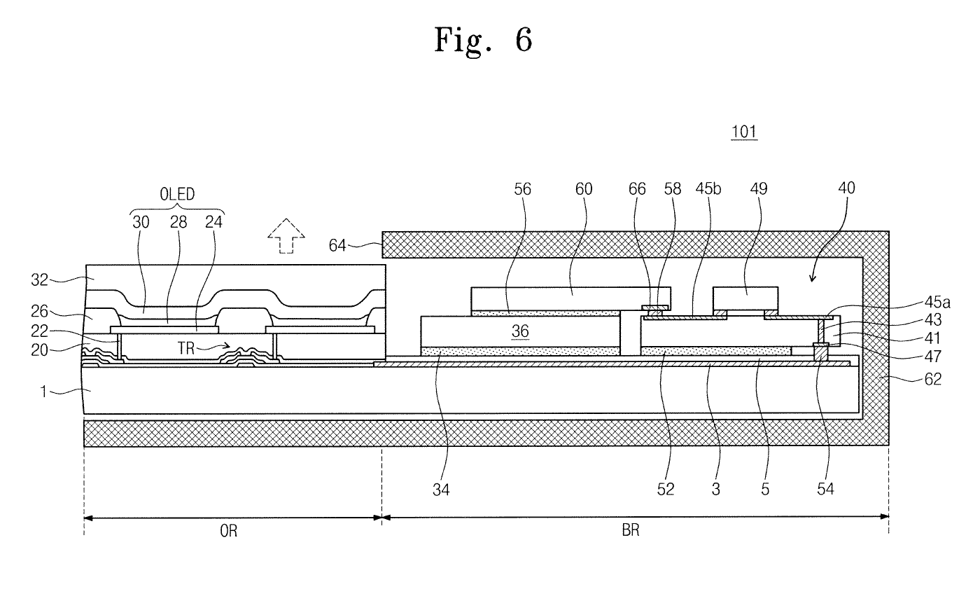

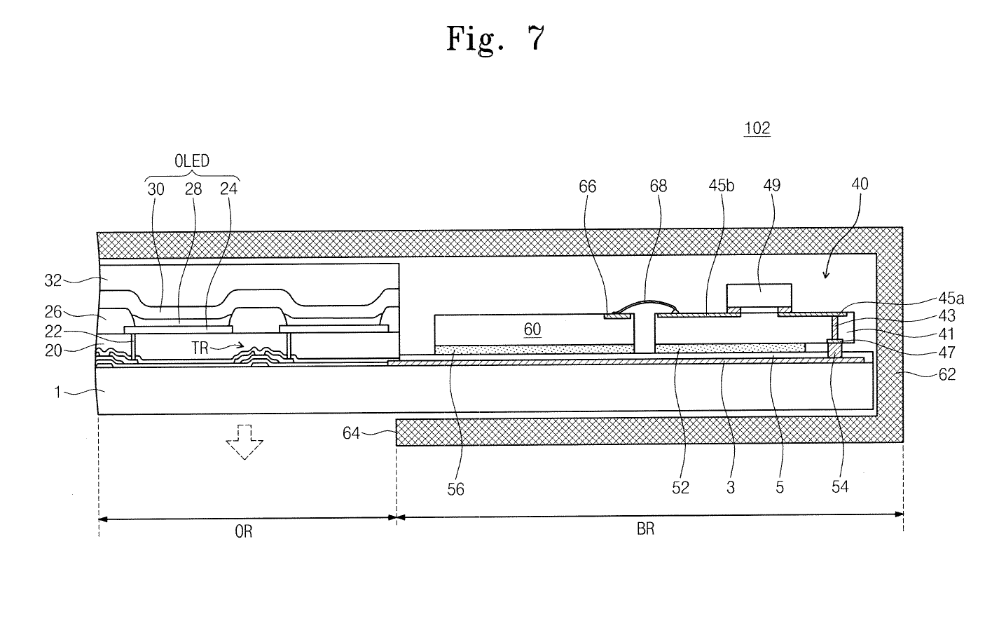

FIGS. 6 and 7 are layouts illustrating display devices according to other embodiments of the inventive concepts.

Referring to FIG. 6, in a display device 101 according to the present embodiment, an opening 64 of a frame 62 may be disposed to be adjacent to a top surface of a display substrate 1. The opening 64 may be disposed so as to be aligned with the display region OR in the direction of light transmission from the display device 101. In the embodiment, light may be outputted by the unit display elements toward the top surface of the sealing layer 32 (e.g., in a direction of the dotted line arrow shown in FIG. 6). In other words, the display device 101 may display an image in a top emission manner. Other elements of the display device 101 may be the same as and/or similar to corresponding elements described with reference to FIG. 1.

Referring to FIG. 7, a display device 102 according to the present embodiment does not include the bracket 36 supporting the circuit substrate 60. The circuit substrate 60 may be disposed at the same height as the package substrate 41 and adjacent to the package substrate 41. In other words, the circuit substrate 60 may be directly bonded to the top surface of the display substrate 1 (e.g., a top surface of the protection layer 5 disposed on the connection terminal 3 formed on the display substrate 1) by the third adhesive member 56. A fifth connection terminal 66 may be disposed of a top surface of the circuit substrate 60. The fifth connection terminal 66 and the fourth connection terminal 45b may be electrically connected to each other through a wire 68. Other elements of the display device 102 may be the same as and/or similar to corresponding elements described with reference to FIG. 1.

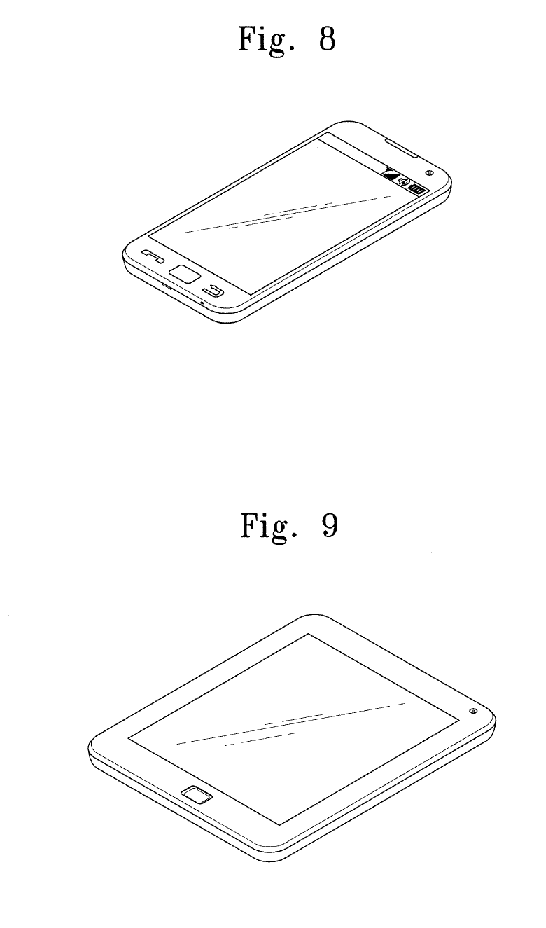

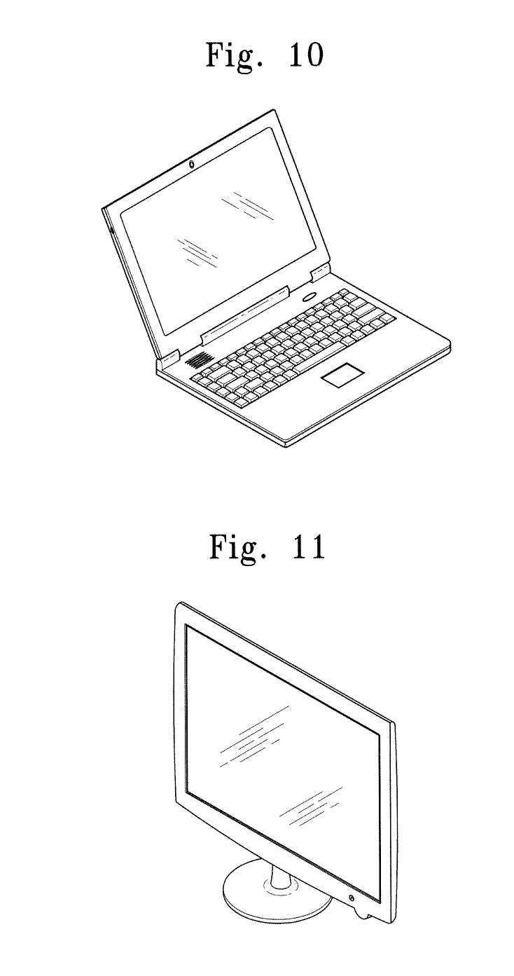

FIGS. 8 to 11 illustrate examples of multimedia devices having display devices configured according to embodiments of the inventive concepts. The display devices 100, 101, and 102 according to embodiments of the inventive concepts may be applied to a mobile or smart phone illustrated in FIG. 8 and/or a tablet or smart tablet illustrated in FIG. 9. Additionally, the display devices 100 to 102 according to embodiments of the inventive concepts may be applied to a notebook computer illustrated in FIG. 10 and/or a television, monitor or smart television illustrated in FIG. 11.

According to embodiments of the inventive concepts, the display device includes the semiconductor package providing electrical signals for driving the unit display elements. The semiconductor package is not folded, but instead has a flat profile. Thus, defects and/or errors of the display device may be reduced. As a result, reliability of the display device may be improved. Additionally, since the semiconductor package is not in contact with the sidewall of the display substrate, the area of the non-display region may be reduced. Thus, an entire size of the display device may be reduced while the area of the display region is maintained.

While the inventive concepts have been described with reference to example embodiments, it will be apparent to those skilled in the art that various changes and modifications may be made without departing from the spirits and scopes of the inventive concepts. Therefore, it should be understood that the above embodiments are illustrative and not limiting. Thus, the scopes of the inventive concepts are to be determined by the broadest permissible interpretation of the following claims and their equivalents, and shall not be restricted or limited by the foregoing description.

What is claimed is:

1. A display device comprising:
a display substrate including a display region and a non-display region;
a plurality of unit display elements disposed on the display substrate in the display region;
a first connection terminal disposed on the display substrate in the non-display region, the first connection terminal electrically connected to at least one of the unit display elements;
a circuit substrate disposed on the display substrate in the non-display region; and
a semiconductor package disposed on the display substrate in the non-display region, the semiconductor package electrically connecting the circuit substrate to the first connection terminal,
wherein the semiconductor package is flat.

2. The display device of claim 1,
wherein the semiconductor package comprises:
a package substrate;
a second connection terminal on a bottom surface of the package substrate;
third and fourth connection terminals spaced apart from each other on a top surface of the package substrate; and
a through-via penetrating the package substrate to electrically connect the second connection terminal to the third connection terminal, and
wherein the first connection terminal is electrically connected to the second connection terminal, and the circuit substrate is electrically connected to the fourth connection terminal.

3. The display device of claim 2, further comprising:
a first interconnecting member disposed between the first and second connection terminals to electrically connect the first connection terminal to the second connection terminal,
wherein the first interconnecting member is an anisotropic conductive film or a solder ball.

4. The display device of claim 2, wherein the package substrate is flexible or hard.

5. The display device of claim 2, wherein the semiconductor package further comprises:
a semiconductor chip mounted on the package substrate and contacting the third and fourth connection terminals,
wherein a bottom surface of the semiconductor chip is parallel to a top surface of the display substrate.

6. The display device of claim 2, wherein the package substrate is disposed under a portion of the circuit substrate,
the display device, further comprising:
a bracket disposed between the circuit substrate and the display substrate to support the circuit substrate.

7. The display device of claim 6, wherein the circuit substrate further comprises:
a fifth connection terminal disposed on a bottom surface of the circuit substrate, and the display device further comprising:
a second interconnecting member disposed between the fifth and fourth connection terminals to electrically connect the fifth connection terminal to the fourth connection terminal.

8. The display device of claim 7, wherein the second interconnecting member is an anisotropic conductive film or a solder ball.

9. The display device of claim 2, wherein the circuit substrate is bonded to the display substrate.

10. The display device of claim 9, wherein the circuit substrate further comprises:
a fifth connection terminal disposed on a top surface of the circuit substrate, the display device, further comprising:
a third interconnecting member electrically connecting the fifth connection terminal to the fourth connection terminal.

11. The display device of claim 10, wherein the third interconnecting member is a wire.

12. The display device of claim 1, further comprising:
a frame surrounding the display substrate, the circuit substrate, and the semiconductor package,
wherein the frame includes an opening disposed so as to be aligned with the display region in a direction of light emission from the unit display elements.

13. The display device of claim 12, wherein each of the plurality of unit display elements includes at least one driving transistor and at least one organic light emitting diode disposed on one surface of the display substrate, and
the opening is disposed adjacent to the one surface of the display substrate.

14. The display device of claim 12, wherein each of the plurality of unit display elements includes at least one driving transistor and at least one organic light emitting diode disposed on one surface of the display substrate, and
the opening is disposed adjacent to a surface of the display substrate opposite to the one surface.

15. The display device of claim 1, wherein each of the unit display elements comprises:
a unit switching element and a unit light emitting element.

16. The display device of claim 1, wherein the display device is an organic light emitting diode display device.

17. The display device of claim 2, wherein all edges of the package substrate are disposed at the same height.

18. A display device comprising:
a display substrate;
a plurality of unit display elements disposed in a display region of the display substrate, wherein each of the plurality of unit display elements includes at least one driving transistor and at least one organic light emitting diode;
a circuit substrate disposed on the display substrate and including circuitry for driving organic light emitting diodes (OLEDs) of the plurality of unit display elements; and
a package substrate disposed on the display substrate, wherein the package substrate is planar and is configured to electrically connect the circuitry of the circuit substrate to the OLEDs of the plurality of unit display elements via driving transistors of the plurality of the plurality of unit display elements.

19. The display device of claim 18, wherein the package substrate has a rectangular cuboid structure.

20. The display device of claim 18, further comprising a semiconductor chip disposed on the package substrate, wherein the circuitry of the circuit substrate is electrically connected to the OLEDs of the plurality of unit display elements via the semiconductor chip.
